(19) United States
(12) Patent Application Publication
(10) Pub. No.: US 2008/0116879 A1
(43) Pub. Date: May 22, 2008

(54) VOLTAGE MEASURING DEVICE

(75) Inventor: MING-CHIH HSIEH, Tu-Cheng (TW)

Correspondence Address: PCE INDUSTRY, INC.;ATT. CHENG-JU CHIANG, 458 E. LAMBERT ROAD, FULLERTON, CA, 92835, US

(73) Assignee: HON HAI PRECISION INDUSTRY CO., LTD., Tu-Cheng (TW)

(21) Appl. No.: 11/778,077

(22) Filed: Jul. 16, 2007

(30) Foreign Application Priority Data
Nov. 20, 2006 (CN) 200610201110.X

(51) Int. Cl. G01R 15/09

(52) U.S. Cl. 324/115

(57) ABSTRACT

A voltage measuring device includes at least two voltage dividing circuits, an analog to digital converter, and a processor. Each voltage dividing circuit is configured for dividing a voltage output by a direct current power supply. The analog to digital converter is configured for converting the divided voltage to a digital signal. The processor is configured for processing the digital signal and selecting one of the at least two voltage dividing circuits, to divide the voltage according to the processed digital signal.

### BACKGROUND OF THE INVENTION

1. Field of the Invention

The present invention relates to a voltage measuring device, and particularly to a voltage measuring device for measuring the value of a voltage output by a direct current (DC) power supply.

2. Description of related art

DC power supplies provide DC voltages for electronic devices such as integrated circuits. When a DC voltage output to an integrated circuit fails to meet the requirement of the integrated circuit, the performance of the integrated circuit can suffer. Therefore, a voltage measuring device is needed to measure the value of the DC voltage.

Referring to FIG. 3, a conventional voltage measuring device includes a voltage dividing circuit 200, an analog to digital converter (ADC) 300, a voltage reference 400, and a processor 500. The voltage dividing circuit 200 converts a DC voltage 100 under test to a smaller voltage. The ADC 300 converts the smaller voltage to a binary digital signal. The processor 500 converts the binary digital signal to a decimal signal. A display unit (not shown) displays the decimal signal and reflects the value of the DC voltage 100. However, the conventional voltage measuring device provides fixed precision in identifying the value of the DC voltage. A smaller DC voltage often needs to be measured with greater precision than a larger DC voltage.

What is needed, therefore, is a voltage measuring device with adjustable precision in identifying a value of a voltage based on the value of the voltage.

### SUMMARY OF THE INVENTION

A voltage measuring device with adjustable precision settings for identifying a value of a voltage based on the value of the voltage is provided. In a preferred embodiment, the voltage measuring device includes a voltage adjusting circuit for reducing a voltage output by a direct current power supply, an analog to digital converter, and a processor. The voltage adjusting circuit includes two electronic switches and a first resistor, the electronic switches having first poles connected to a first terminal of the first resistor respectively via a second resistor and a third resistor, and second poles connected to ground, a second terminal of the first resistor being connected to the direct current power supply. The analog to digital converter is connected to the first terminal of the first resistor, for converting reduced voltages to digital signals. The processor is connected to the analog to digital converter and a third pole of each electronic switch, the processor capable of processing the digital signals, and selecting one of the two electronic switches to turn on based on the initial one of the processed digital signals such that the voltage adjusting circuit is capable of outputting a rerouted reduced voltage to the analog to digital converter which outputs a rerouted digital signal to the processor for further processing.

Other advantages and novel features will become more apparent from the following detailed description when taken in conjunction with the accompanying drawings, in which:

### BRIEF DESCRIPTION OF THE DRAWINGS

FIG. 1 is a block diagram of a voltage measuring device in accordance with a preferred embodiment of the present invention;

FIG. 2 is a circuit diagram of a direct current power supply, a voltage adjusting circuit, and a protecting circuit of the voltage measuring device of FIG. 1; and

FIG. 3 is a schematic diagram of a conventional voltage measuring device.

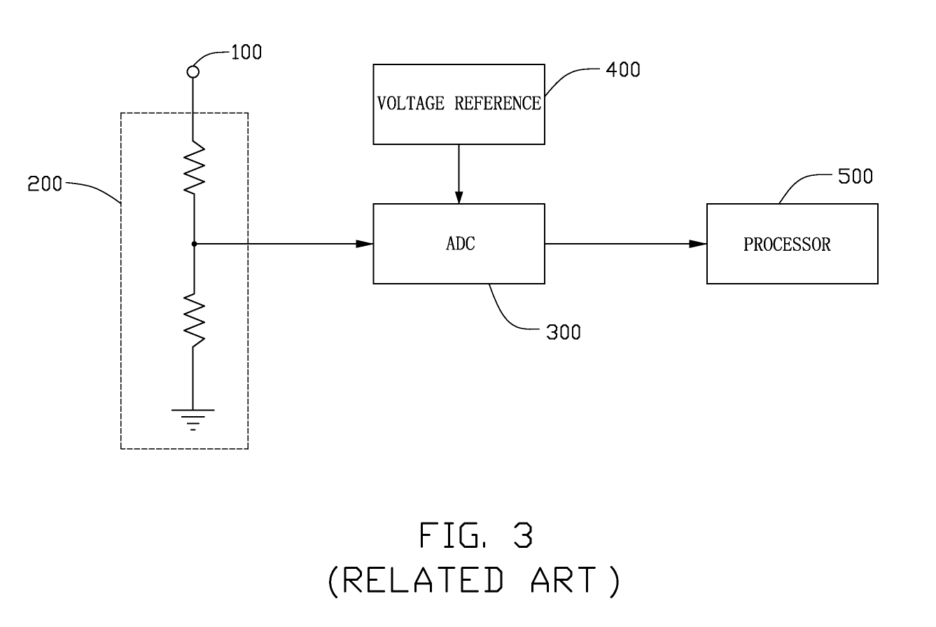

### DETAILED DESCRIPTION OF THE INVENTION

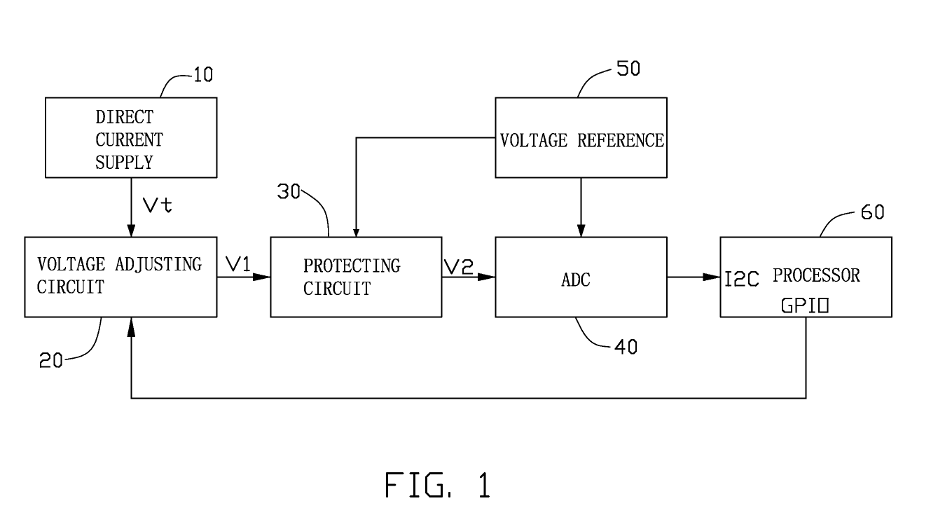

Referring to FIG. 1, a voltage measuring device in accordance with an embodiment of the present invention includes a voltage adjusting circuit 20, a protecting circuit 30, a 10-bit analog to digital converter (ADC) 40, a voltage reference 50, and a processor 60. A direct current (DC) power supply 10 outputs an under test voltage Vt to the voltage adjusting circuit 20.

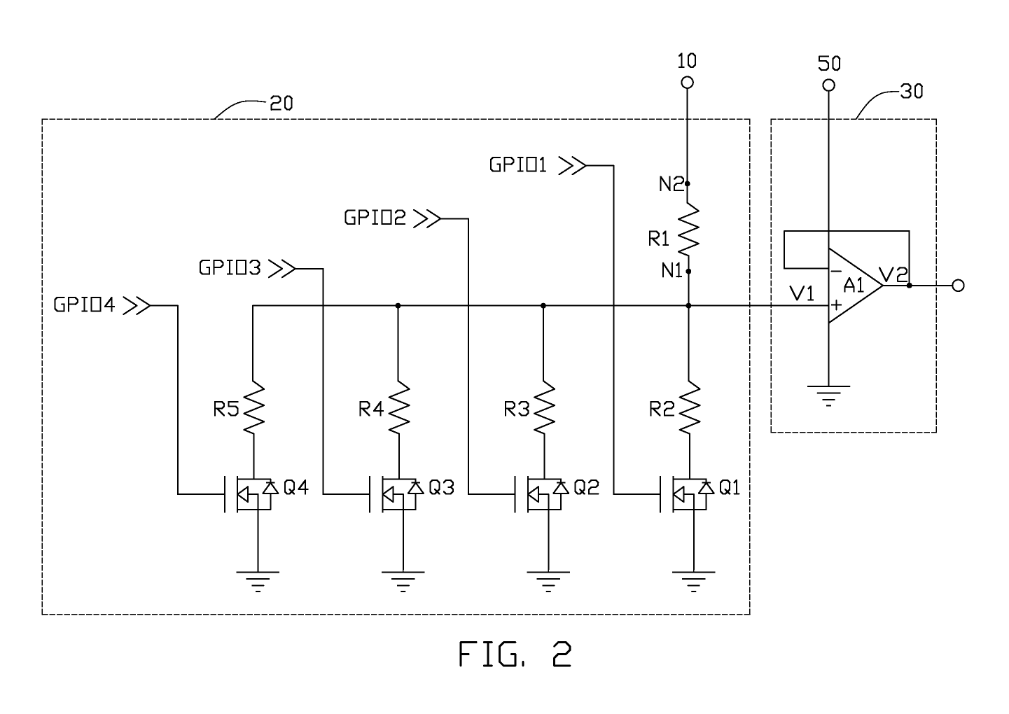

Referring also to FIG. 2, the voltage adjusting circuit 20 includes MOSFETs Q1, Q2, Q3, Q4, and resistors R1, R2, R3, R4, R5. The MOSFETs Q1, Q2, Q3, Q4 have first poles, namely the drains, connected to a first terminal N1 of the resistor R1 respectively via the resistors R2, R3, R4, R5, and second poles, namely the sources, connected to ground. A second terminal N2 of the resistor R1 is connected to the DC power supply 10.

The protecting circuit 30 includes an amplifier A1. The amplifier A1 has a non-inverting input connected to the first terminal N1 of the resistor R1, an output connected to the ADC 40, and an inverting input connected to the output of the amplifier A1. The voltage reference 50 provides a working voltage for the amplifier A1 and the ADC 40. When a voltage VI input to the non-inverting input is equal to or less than the voltage reference 50, a voltage V2 output by the amplifier A1 equals the voltage V1. When the voltage V1 is more than the voltage reference 50, the voltage V2 output by the amplifier A1 equals the voltage reference 50. Therefore, the voltage V2 received by the ADC 40 is not more than the working voltage of the ADC40. The ADC 40 is thus protected. The processor 60 includes an I2C port connected to an output of the ADC 40, and input/output ports GPIO1, GPIO2, GPIO3, GPIO4 respectively connected to third poles, namely the gates of the MOSFETs Q1, Q2, Q3, Q4.

The voltage Vt output by the DC power supply 10 is within a range of 0 to 60 volts. The voltage reference 50 is 4.096 volts, and the voltage at the first terminal N1 remains fixed at 4.096 volts as well if the following conditions are met. When the voltage Vt is 60 volts, the MOSFET Q1 is turned on, and the MOSFETs Q2, Q3, Q4 are turned off, the first terminal N1 of the resistor R1 has a voltage of 4.096 volts because of the resistance of the resistors R1, R2 satisfying the following formula: R2/(R1+R2)=4.096/60. When the voltage Vt is 45 volts, the MOSFET Q2 is turned on, and the MOSFETs Q1, Q3, Q4 are turned off, the first terminal N1 still has a voltage of 4.096 volts because of the resistance of the resistors R1, R3 satisfying the following formula: R3/(R1+R3)=4.096/45. When the voltage Vt is 30 volts, the MOSFET Q3 is turned on, and the MOSFETs Q1, Q2, Q4 are turned off, the first terminal N1 still has a voltage of 4.096 volts because of the resistance of the resistors R1, R4 satisfying the following formula: R4/(R1+R4)=4.096/30. When the voltage Vt is 15 volts, the MOSFET Q4 is turned on, and the MOSFETs Q1, Q2, Q3 are turned off, the first terminal N1 still has a voltage of 4.096 volts because of the resistance of the resistors R1, R5 satisfying the following formula: R5/(R1+R5)=4.096/15.

Initially, the input/output port GPIO1 provides a high level signal for the MOSFET Q1, and the input/output ports GPIO2, GPIO3, GPIO4 provide low level signals for the MOSFETs Q2, Q3, Q4. The MOSFET Q1 is turned on. The MOSFETs Q2, Q3, Q4 is turned off. For example, if the DC power supply 10 outputs the voltage Vt at about 23.3 volts, the voltage Vt is divided by a first voltage dividing circuit made up of the resistors R1, R2. The initial divided voltage is delivered by the protecting circuit 30, and converted to an initial digital signal by the ADC 40. The processor 60 processes the initial digital signal, and determines the voltage Vt is within a range of 15 to 30 volts. Then the input/output port GPIO3 provides a high level signal for the MOSFET Q3, and the input/output ports GPIO1, GPIO2, GPIO4 provide low level signals for the MOSFETs Q1, Q2, Q4. The MOSFET Q3 is turned on. The MOSFETs Q1, Q2, Q4 are turned off. The voltage Vt is divided by a second voltage dividing circuit made up of the resistors R1, R4. A rerouted divided voltage is delivered by the protecting circuit 30, and then converted to a rerouted digital signal by the ADC 40. The processor 60 converts the rerouted digital signal (binary signal) to a decimal signal. A display unit (not shown) displays the decimal signal and reflects the value of the voltage Vt.

If the voltage Vt is measured according to the first digital signal, the precision in identifying the value of the voltage Vt is found using the following expression:60/2¹⁰. If the voltage Vt is measured according to the second digital signal, the precision in identifying the value of the voltage Vt is thus found using the follow expression: 30/2¹⁰. Therefore, greater precision in identifying the value of the voltage Vt is selected by the processor 60 based on the value of the voltage Vt. Different ranges of voltages corresponding to desired precision can be programmed into the processor as required.

Likewise, when the voltage output by the DC power supply 10 is within a range of 30-45 volts, a third voltage dividing circuit made up of the resistors R1, R3 can be selected to reach an precision of 45/2¹⁰. When the voltage output by the DC power supply 10 is within a range of 0-15 volts, a fourth voltage dividing circuit made up of the resistors R1, R5 can be selected to reach an precision of 15/2¹⁰.

The MOSFETs can be other electronic switches, e.g. bipolar junction transistors (BJTs). A collector, an emitter, and a base of a BJT respectively serve as the first, second, and the third poles.

The embodiments were chosen and described in order to explain the principles of the invention and their practical application so as to enable others skilled in the art to utilize the invention and various embodiments and with various modifications as are suited to the particular use contemplated. Alternative embodiments will become apparent to those skilled in the art to which the present invention pertains without departing from its spirit and scope. Accordingly, the scope of the present invention is defined by the appended claims rather than the foregoing description and the exemplary embodiments described therein.

What is claimed is:

1. A voltage measuring device for measuring a voltage output by a direct current power supply, the voltage measuring device comprising:
a voltage adjusting circuit for reducing the voltage output by the direct current power supply, the voltage adjusting circuit comprising two electronic switches and a first resistor, the electronic switches having first poles connected to a first terminal of the first resistor respectively via a second resistor and a third resistor, and second poles connected to ground, a second terminal of the first resistor configured for being connected to the direct current power supply;
an analog to digital converter connected to the first terminal of the first resistor, for converting reduced voltages to digital signals; and
a processor connected to the analog to digital converter and a third pole of each electronic switch, the processor capable of processing the digital signals, and selecting one of the two electronic switches to turn on based on the initial one of the processed digital signals such that the voltage adjusting circuit is capable of outputting a rerouted reduced voltage to the analog to digital converter which outputs a rerouted digital signal to the processor for further processing.

2. The voltage measuring device as claimed in claim 1, further comprising a protecting circuit, the protecting circuit comprising an amplifier, the amplifier having a non-inverting input connected to the first terminal of the first resistor, an output connected to the analog to digital converter, and an inverting input connected to the output of the amplifier.

3. The voltage measuring device as claimed in claim 1, wherein the processor comprises two input/output ports respectively connected to the third poles of the electronic switches.

4. The voltage measuring device as claimed in claim 1, wherein the electronic switches are MOSFETs or BJTs.

5. The voltage measuring device as claimed in claim 4, wherein the first pole of each MOSFET is a drain, the second pole of each MOSFET is a source, and the third pole of each MOSFET is a gate.

6. A voltage measuring device for measuring a voltage output by a direct current power supply, the voltage measuring device comprising: at least two voltage dividing circuits corresponding to two precision settings each corresponding to a discrete voltage range configured for being selectively connected to the direct current power supply to divide the voltage output by the direct current power supply;
an analog to digital converter configured for converting the divided voltage to a digital signal; and
a processor configured for processing the digital signal, and selecting one of the at least two voltage dividing circuits to divide the voltage according to the voltage range within which the voltage output by the direct current power supply falls.

7. The voltage measuring device as claimed in claim 6, wherein one of the at least two voltage dividing circuits comprises a first resistor, a second resistor connected to the first resistor in series, and a first electronic switch, the first electronic switch has a first pole connected to a first terminal of the first resistor via the second resistor, a second pole connected to ground, and a third pole connected to an input/output port of the processor, the first terminal of the first resistor outputs the divided voltage, a second terminal of the first resistor is connected to the direct current power supply, wherein the processor selects the selected one of the at least two voltage dividing circuits based on the divided voltage output by the first terminal of the first resistor when the first electronic switch turns on.

8. The voltage measuring device as claimed in claim 7, wherein another one of the at least two voltage dividing circuits comprises the first resistor, a third resistor connected to the first resistor in series, and a second electronic switch, the second electronic switch has a first pole connected to the first terminal of the first resistor via the third resistor, a second pole connected to ground, and a third pole connected to another input/output port of the processor, wherein if the voltage output by the direct current power supply falls within the voltage range corresponding to said another one of the at least two voltage dividing circuits the second electronic switch is selected to turn on while the first electronic switch is turned off.

9. The voltage measuring device as claimed in claim 8, further comprising a protecting circuit, the protecting circuit comprising an amplifier, the amplifier having a non-inverting input connected to the first terminal of the first resistor, an output connected to the analog to digital converter, and an inverting input connected to the output of the amplifier.

10. The voltage measuring device as claimed in claim 8, wherein the electronic switches are MOSFETs or BJTs.

11. The voltage measuring device as claimed in claim 10, wherein the first pole of each MOSFET is a drain, the second pole of each MOSFET is a source, and the third pole of each MOSFET is a gate.

12. A method for measuring a voltage output by a direct current power supply by a voltage measuring device which comprises an initial voltage dividing circuit corresponding to one measuring precision setting corresponding to one discrete voltage range and a selective voltage dividing circuit corresponding to another one measuring precision setting corresponding to another discrete voltage range, an analog to digital converter; and a processor, the method comprising:
connecting the initial voltage dividing circuit between the power supply and the analog to digital converter;
the initial voltage dividing circuit outputting an initial divided voltage to the analog to digital converter;
the analog to digital converter converting the initial divided voltage to an initial digital signal and outputting the initial digital signal to the processor;
the processor processing the initial digital signal at said one measuring precision setting and selecting one of the initial voltage dividing circuit and the selective voltage dividing circuit to connect the power supply with the analog to digital converter based on the processed initial digital signal such that the analog to digital converter receives a rerouted divided voltage output by the selected one of the initial voltage dividing circuit and the selective voltage dividing circuit and outputs a rerouted digital signal to the processor for further processing at a measuring precision setting corresponding to the selected one of the initial voltage dividing circuit and the selective voltage dividing circuit.

13. The method as claimed in claim 12, wherein the rerouted digital signal is a binary signal and converted to a decimal signal by the processor, and the method further comprises displaying the decimal signal which reflects the value of the voltage output by the direct current power supply.
